(19) United States
(12) Patent Application Publication
(10) Pub. No.: US 2026/0047073 A1
(43) Pub. Date: Feb. 12, 2026

(54) SEMICONDUCTOR DEVICE AND METHOD FOR FABRICATING THE SAME

(71) Applicant: SK hynix Inc., Gyeonggi-do (KR)

(72) Inventors: Sang Won CHO, Gyeonggi-do (KR); Woo Young PARK, Gyeonggi-do (KR); Ho Joon SONG, Gyeonggi-do (KR)

(21) Appl. No.: 19/182,597

(22) Filed: Apr. 18, 2025

(30) Foreign Application Priority Data
Aug. 7, 2024 (KR) 10-2024-0105392

(51) Int. Cl. H10B 12/00

(52) U.S. Cl. CPC H10B 12/315; H10B 12/033

(57) ABSTRACT

Disclosed are a semiconductor device capable of preventing leakage current between cells, and a method for fabricating the semiconductor device. The semiconductor device includes a lower electrode formed over a substrate; and a supporter covering an upper surface and a portion of a side of the lower electrode and including a material having a higher work function than a material of the lower electrode.

### CROSS-REFERENCE TO RELATED APPLICATIONS

The present application claims priority under 35 U.S.C 119(a) to Korean Patent Application No. 10-2024-0105392, filed on Aug. 7, 2024, which is incorporated herein by reference in its entirety.

### BACKGROUND

### 1. Field

Embodiments of the present disclosure relate generally to a semiconductor device and a method for fabricating the same, and more particularly, to a semiconductor device including a capacitor, and a method for fabricating the semiconductor device.

### 2. Description of the Related Art

Recently, as the aspect ratio of capacitors is increasing, supporters are being applied to prevent capacitors from collapsing. Also, as semiconductor devices are integrated, the distance between cells is getting closer. However, the supporters may cause an issue of leakage current.

### SUMMARY

Embodiments of the present disclosure are directed to a semiconductor device capable of preventing leakage current between cells, and a method for fabricating the semiconductor device.

In accordance with an embodiment of the present disclosure, a semiconductor device includes a lower electrode formed over a substrate, and a supporter covering an upper surface and a portion of a side of the lower electrode. The supporter includes a material having a higher work function than a material of the lower electrode.

In accordance with another embodiment of the present disclosure, a semiconductor device includes a lower electrode formed over a substrate; a lower supporter surrounding a portion of an outer wall of the lower electrode; and an upper supporter covering an upper surface and a portion of a side of the lower electrode and including a high band gap material having a higher band gap than a material of the lower supporter.

In accordance with another embodiment of the present disclosure, a method for fabricating a semiconductor device includes forming a mold structure including an opening over a substrate; forming a lower electrode gap-filling the opening; etching the mold structure to a predetermined depth to expose an upper portion of the lower electrode; performing a treatment process onto the exposed upper surface of the lower electrode to change the exposed upper surface of the lower electrode with a supporter liner having a higher work function than the lower electrode; and forming a supporter layer over the supporter liner.

In accordance with another embodiment of the present disclosure, a method for fabricating a semiconductor device includes forming a mold structure including an opening over a substrate; forming a lower electrode gap-filling the opening; etching the mold structure to a predetermined depth to expose an upper portion of the lower electrode; forming an upper supporter including a material having a higher band gap than silicon nitride to cover the exposed upper portion of the lower electrode.

In accordance with another embodiment of the present disclosure, a lower electrode formed over a substrate; and a supporter covering an upper surface and a portion of a side of the lower electrode and including a material having a higher band gap than silicon nitride.

In accordance with another embodiment of the present disclosure, a lower electrode formed over a substrate; and a supporter including a supporter liner covering an upper surface and a portion of a side of the lower electrode and including a material having a higher work function than a material of the lower electrode.

These and other features and advantages of the embodiments of the present disclosure will become better understood from those with ordinary skill in the art from the following drawings and embodiments.

### BRIEF DESCRIPTION OF THE DRAWINGS

FIG. 1 is a cross-sectional view illustrating a semiconductor device in accordance with an embodiment of the present disclosure.

FIGS. 2A to 2O are process cross-sectional views illustrating a method for fabricating a semiconductor device in accordance with an embodiment of the present disclosure.

FIG. 3 is a cross-sectional view illustrating a semiconductor device in accordance with another embodiment of the present disclosure.

FIG. 4 is a cross-sectional view illustrating a semiconductor device in accordance with yet another embodiment of the present disclosure.

FIGS. 5A to 5O are process cross-sectional views illustrating a method for fabricating a semiconductor device in accordance with another embodiment of the present disclosure.

FIGS. 6 to 8 are cross-sectional views illustrating semiconductor devices in accordance with other embodiments of the present disclosure.

### DETAILED DESCRIPTION

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated to clearly illustrate certain features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

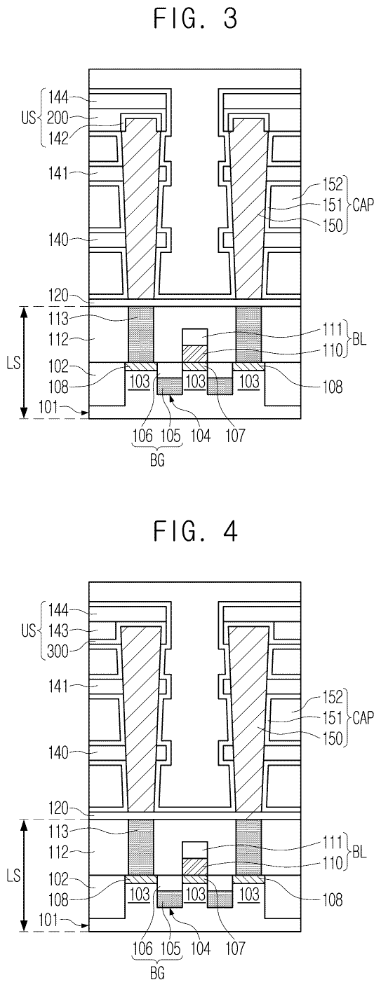

FIG. 1 is a cross-sectional view illustrating a semiconductor device in accordance with an embodiment of the present disclosure. FIG. 3 is a cross-sectional view illustrating a semiconductor device in accordance with another embodiment of the present disclosure.

Referring to FIG. 1, the semiconductor device may include a substrate 101, a lower electrode 150 formed over the substrate 101, and a supporter covering an upper surface and a portion of a side of the lower electrode 150 and including a material having a higher work function than that of the lower electrode 150.

The lower structure LS may include a gate structure BG disposed in the substrate 101. The lower structure LS may also include a bit line BL, and a storage node contact 113 that are disposed over the substrate 101. The substrate 101 may be made of a material suitable for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include another semiconductor material, such as germanium. The substrate 101 may also include a III/V-group semiconductor substrate, such as a compound semiconductor substrate, such as gallium arsenide (GaAs). The substrate 101 may also include an SOI (Silicon-On-Insulator) substrate.

An isolation layer 102 and an active region 103 may be formed in the substrate 101. A plurality of active regions 103 may be defined by the isolation layer 102.

A gate structure BG may be disposed in the substrate 101. The gate structure BG may include a buried gate structure disposed at a lower level than the upper surface of the substrate 101. Although FIG. 1 illustrates a buried gate structure disposed at a lower level than the upper surface of the substrate 101, the technical concepts and scope of the present disclosure are not limited thereto. Different gate structures including, for example, a recess gate, a fin gate, a planar gate and the like may be applied.

The gate structure BG may include a stacked structure of a gate electrode 105 and a gate capping layer 106 gap-filling a gate trench 104. A gate dielectric layer may be interposed between the gate trench 104 and the stacked structure of the gate electrode 105 and the gate capping layer 106.

For example, the gate trench 104 may be formed in the substrate 101. The bottom surface of the gate trench 104 may be disposed at a higher level than the bottom surface of the isolation layer 102. The gate trench 104 may have a shallower depth than the isolation layer 102. According to another embodiment of the present disclosure, the bottom portion of the gate trench 104 may have a curvature. According to another embodiment of the present disclosure, the isolation layer 102 of a direction in which the gate trench 104 extends may be etched to a predetermined depth to form a fin in the active region 103.

The gate electrode 105 may fill the bottom portion of the gate trench 104. The gate capping layer 106 may fill the remaining portion of the gate trench 104 over the gate electrode 105. The upper surface of the gate capping layer 106 may be disposed at the same level as the upper surface of the substrate 101. The upper surface of the gate capping layer 106 may be coplanar with the upper surface of the substrate 101.

First and second impurity regions 107 and 108 may be formed in the substrate 101. The first and second impurity regions 107 and 108 may be referred to as ‘first and second source/drain regions’, respectively. The first and second impurity regions 107 and 108 may be spaced apart from each other by the gate trench 104. Accordingly, the gate electrode 105 and the first and second impurity regions 107 and 108 may become a cell transistor. The cell transistor may improve the short channel effect due to the gate electrode 105 having a buried gate structure.

An inter-layer dielectric layer 112 may be disposed over the substrate 101. For example, the inter-layer dielectric layer 112 may be made of a suitable dielectric material such as, for example, at least one of silicon nitride (Si₃N₄), silicon oxide (SiO₂), and silicon oxynitride (SiON). According to another embodiment of the present disclosure, the inter-layer dielectric layer 112 may include one or more spaces.

A bit line structure BL and a storage node contact 113 may be disposed in the inter-layer dielectric layer 112. The bit line structure BL may be formed to be coupled to the first source/drain region 107 between the gate structures BG.

The storage node contacts 113 may penetrate the inter-layer dielectric layer 112 and may be coupled to respective second source/drain region 107 on both sides of the gate structure BG.

An etch stop pattern 120 may be disposed over the inter-layer dielectric layer 112. The etch stop pattern 120 may cover the inter-layer dielectric layer 112 and expose the storage node contact 113. The etch stop pattern 120 may include a dielectric material. For example, the etch stop pattern 120 may include silicon nitride.

Lower electrodes 150 may be respectively disposed over the storage node contacts 113. The lower electrodes 150 penetrating the etch stop pattern 120 to contact the storage node contacts 113, respectively. The lower electrodes 150 may have a high aspect ratio. Here, the high aspect ratio may refer to the ratio of height to width. The lower electrode 150 may refer to an aspect ratio which is greater than approximately 1:1. The lower electrode 150 may have an aspect ratio of approximately 10:1 or more. The height of each lower electrode 150 may be approximately 5000 Å or more. For example, the lower electrodes 150 may have a pillar shape. According to another embodiment of the present disclosure, the lower electrodes 150 may include a cylinder shape.

The lower electrodes 150 may include a conductive material. For example, the lower electrodes 150 may include cobalt (Co), titanium (Ti), nickel (Ni), tungsten (W), molybdenum (Mo), gold (Pt), ruthenium (Ru), iridium (Ir), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), tungsten nitride (WN), or a combination thereof. According to an embodiment of the present disclosure, the lower electrodes 150 may be formed of titanium nitride. The lower electrode 150 may include titanium nitride (ALD-TiN) that is formed by an Atomic Layer Deposition (ALD) process. According to another embodiment of the present disclosure, the lower electrode 150 may include a stacked structure of TiN/TiSiN.

A plurality of supporters 140, 141 and US may be disposed over the substrate 101. The supporters 140, 141 and US may be spaced apart from each other in a direction perpendicular to the surface of the substrate 101. The supporters 140, 141 and US may include a first supporter 140, a second supporter 141, and an upper supporter US. The first and second supporters 140 and 141 may be referred to as ‘lower supporters’. The number of the lower supporters may be increased or decreased as needed.

The supporters 140, 141 and US may be disposed between the lower electrodes 150. The supporters 140, 141 and US may contact a side of each lower electrode 150 to surround the side of each lower electrode 150. The supporters 140, 141 and US may physically support the lower electrodes 150. The supporters 140, 141 and US may contact the side walls of the neighboring lower electrodes 150. The upper supporter US may be thicker than each of the first and second supporters 140 and 141.

The first and second supporters 140 and 141 may include a dielectric material. For example, the first and second supporters 140 and 141 may include silicon nitride.

The upper supporter US may be formed in multiple layers. The upper supporter US may be disposed between the neighboring lower electrodes 150 and also over the lower electrodes 150. The upper supporter US may include a stacked structure of a supporter liner 142, a first upper supporter 143, and a second upper supporter 144.

The supporter liner 142 may cover the upper surface and a portion of a side of each lower electrode 150 that is near the upper surface of each lower electrode. The first upper supporter 143 may gap-fill the upper portion of the supporter liner 142 and between the supporter liners 142. The second upper supporter 144 may be disposed over the first upper supporter 143.

The upper supporter US may include a material having a higher work function than that of the lower electrode 150. According to an embodiment of the present disclosure, the supporter liner 142 may include a material having a higher work function than that of the lower electrode 150. The supporter liner 142 may be formed through a treatment process. The supporter liner 142 may be a region where the surface of the lower electrode 150 is changed with a material having a higher work function than that of the lower electrode 150 by performing a treatment process.

For example, the treatment process may include an oxidation process or a nitridation process.

The supporter liner 142 may be of an oxide, a nitride, or an oxynitride including the same metal material as the metal material of the lower electrode 150.

The first and second upper supporters 143 and 144 may include the same material. For example, the first and second upper supporters may include a dielectric material selected from the group including SiOC, SiBN, SiBCN, SiCN, SiON, SiN, Si, and doped SiN.

According to another embodiment of the present disclosure, as illustrated in FIG. 3, a first upper supporter 200 may include a high band gap material. The high band gap material may include a material having a higher band gap than silicon nitride (SiN). The high band gap material may be formed through a deposition process. For example, the high band gap material may include one oxide selected from the group including AlO, SiO, BeO, MgO, CaO, and SrO, or one nitride selected from the group including doped SiN, AlN, MoN, WN, and TaN.

The dielectric layer 151 may uniformly cover the surfaces of the lower electrodes 150 and the supporters 140, 141 and US. However, the dielectric layer 151 may not be formed between the supporters 140, 141 and US and the lower electrode 150.

The dielectric layer 151 may include a high-k material having a higher dielectric constant than silicon oxide. The high-k material may include zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃). According to another embodiment of the present disclosure, the dielectric layer 151 may be formed of a composite layer including two or more layers of the aforementioned high-k materials. According to an embodiment of the present disclosure, the dielectric layer 151 may be formed, for example, of a zirconium oxide-based material which has excellent leakage current characteristics and lowers sufficiently the equivalent oxide thickness (EOT). For example, the dielectric layer 151 may include one of ZAZ (ZrO₂/Al₂O₃/ZrO₂), TZAZ (TiO₂/ZrO₂/Al₂O₃/ZrO₂), TZAZT (TiO₂/ZrO₂/Al₂O₃/ZrO₂/TiO₂), ZAZT (ZrO₂/Al₂O₃/ZrO₂/TiO₂), TZ (TiO₂/ZrO₂), and ZAZAT (ZrO₂/Al₂O₃/ZrO₂/Al₂O₃/TiO₂). In the dielectric layer stack such as TZAZ, TZAZT, ZAZT, TZ, and ZAZAT, the TiO₂ may be replaced with Ta₂O₅. The dielectric layer 151 may be formed, for example, by a Chemical Vapor Deposition (CVD) process. The dielectric layer 151 may also be formed by an Atomic Layer Deposition (ALD) process for obtaining excellent, uniform coverage.

An upper electrode 152 may be formed over the dielectric layer 151. The upper electrode 152 may include a metal-based material. For example, the upper electrode 152 may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. The upper electrode 152 may be formed, for example, by a Low-Pressure Chemical Vapor Deposition (LPCVD) process, a Plasma Enhanced Chemical Vapor Deposition (PECVD) process, or an Atomic Layer Deposition (ALD) process. According to an embodiment of the present disclosure, the upper electrode 152 may include titanium nitride (ALD-TiN) that is formed by an atomic layer deposition (ALD) process.

According to another embodiment of the present disclosure, the upper electrode 152 may have a multi-layer structure. The upper electrode 152 may be formed by sequentially stacking a lower metal-containing layer, a silicon germanium layer, and an upper metal-containing layer. The lower metal-containing layer and the upper metal-containing layer may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. For example, the lower metal-containing layer may be titanium nitride, and the upper metal-containing layer may be WN/W in which tungsten nitride and tungsten are stacked. The silicon germanium layer may be doped with boron. According to another embodiment of the present disclosure, the upper electrode 152 may include a stacked structure of TiSiN/TiN or molybdenum nitride (MoN).

As described above, the leakage current between cells may be mitigated or minimized by forming the supporter liner 142 of a material having a higher work function than that of the lower electrode 150. Also, according to the embodiment of the present disclosure, as illustrated in FIG. 3, the leakage current between cells may be mitigated or minimized by forming the first upper supporter 200 of a high band gap material while forming the supporter liner 142 of a material having a higher work function than that of the lower electrode 150.

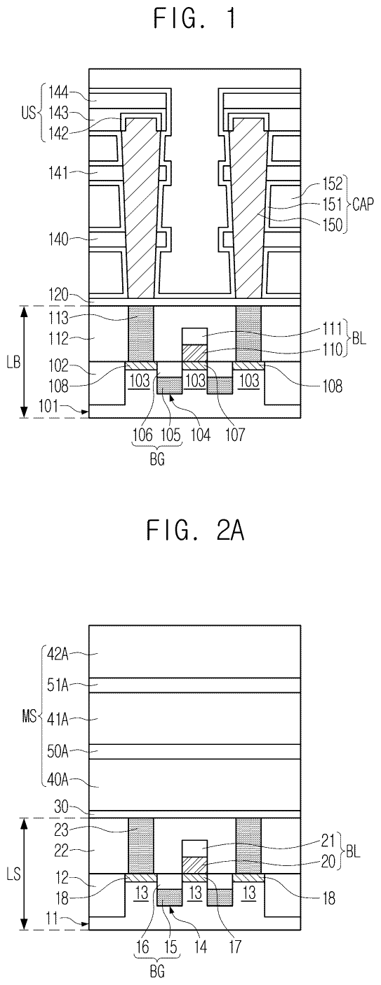

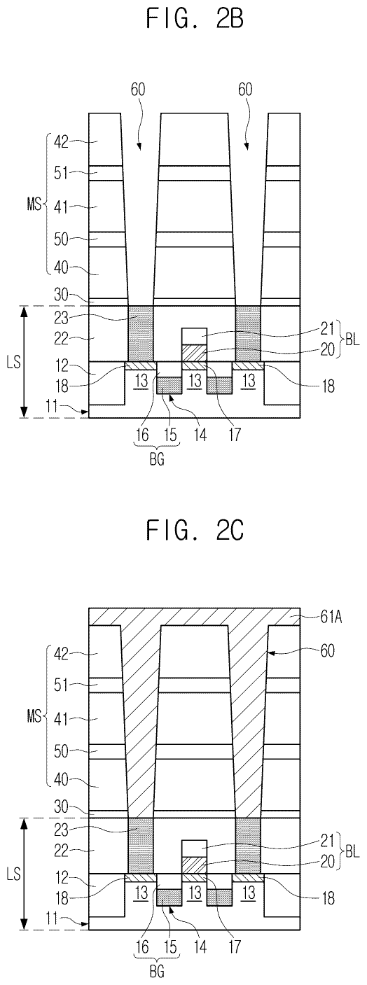

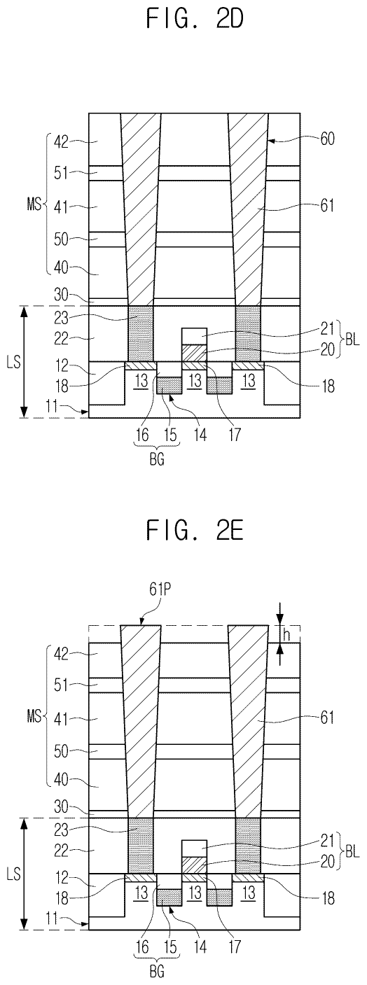

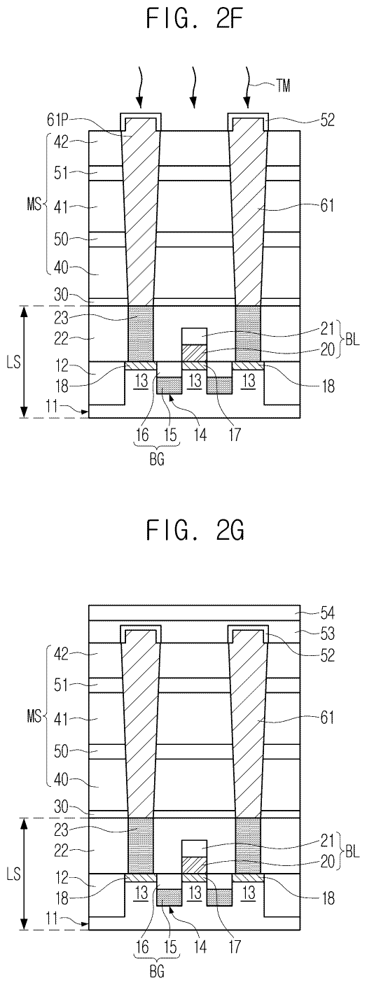

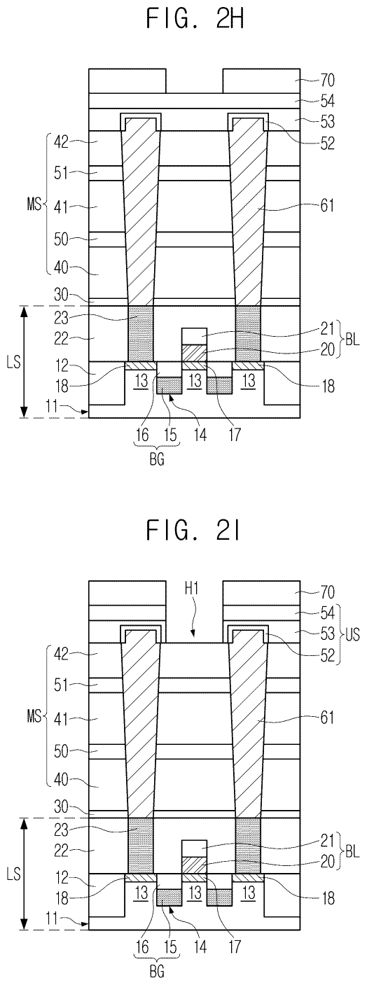

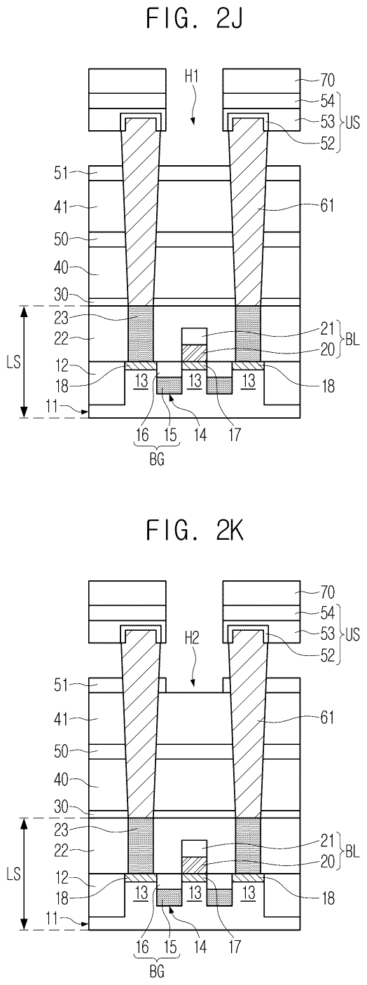

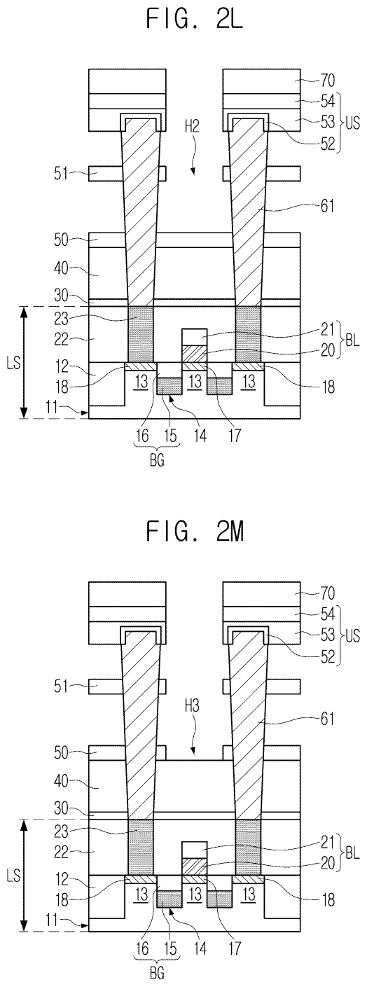

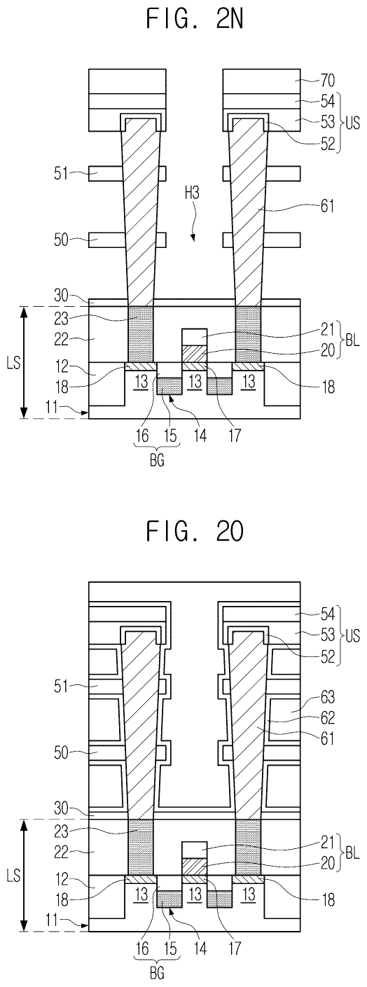

FIGS. 2A to 2O are process cross-sectional views illustrating a method for fabricating a semiconductor device in accordance with an embodiment of the present disclosure.

Referring to FIG. 2A, an etch stop layer 30 and a mold structure MS may be sequentially formed over a substrate 11 including a lower structure LS.

The lower structure LS may include a gate structure BG disposed in the substrate 11. The lower structure LS may also include a bit line BL and a storage node contact 23 that are disposed over the substrate 11.

The substrate 11 may be made of a material suitable for semiconductor processing. The substrate 11 may include a semiconductor substrate. The substrate 11 may be formed of a material containing silicon. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include another semiconductor material, such as germanium. The substrate 11 may include a III/V-group semiconductor substrate, for example, a compound semiconductor substrate, such as gallium arsenide (GaAs). The substrate 11 may include an SOI (Silicon-On-Insulator) substrate.

An isolation layer 12 may be formed over the substrate 11 defining a plurality of active regions 13.

A gate structure BG may be disposed over the substrate 11. The gate structure BG may include a buried gate structure which is disposed at a lower level than the upper surface of the substrate 11. Although FIG. 2A illustrates a buried gate structure disposed at a lower level than the upper surface of the substrate 11, the technical concepts and scope of the present disclosure are not limited thereto. Any suitable gate structure including a recess gate, a fin gate, a planar gate and the like may be applied.

The gate structure BG may include a stacked structure of a gate electrode 15 and a gate capping layer 16 gap-filling a gate trench 14. A gate dielectric layer (not shown) may be interposed between the gate trench 14 and the stacked structure of the gate electrode 15 and the gate capping layer 16.

For example, the gate trench 14 may be formed inside substrate 11 with the bottom surface of the gate trench 14 disposed at a higher level than the bottom surface of the isolation layer 12. The gate trench 14 may have a shallower depth than the isolation layer 12. According to another embodiment of the present disclosure, the bottom portion of the gate trench 14 may have a curvature. According to another embodiment of the present disclosure, the isolation layer 102 of a direction in which the gate trench 14 extends may be etched to a predetermined depth to form a fin in the active region 13.

The gate electrode 15 may fill the bottom portion of the gate trench 14. The gate capping layer 16 may fill the remaining portion of the gate trench 14 over the gate electrode 15. The upper surface of the gate capping layer 16 may be disposed at the same level as the upper surface of the substrate 11. Hence, the upper surface of the gate capping layer 16 may be coplanar with the upper surface of the substrate 11.

First and second impurity regions 17 and 18 may be formed over the substrate 11. The first and second impurity regions 17 and 18 may be referred to as ‘first and second source/drain regions’, respectively. The first and second impurity regions 17 and 18 may be spaced apart from each other by the gate trench 14. The gate electrode 15 and the first and second impurity regions 17 and 18 may become a cell transistor. The cell transistor may improve the short channel effect due to the gate electrode 15 having a buried gate structure.

An inter-layer dielectric layer 22 may be disposed over the substrate 11. For example, the inter-layer dielectric layer 22 may include a suitable dielectric material including, for example, at least one of silicon nitride, silicon oxide, and silicon oxynitride. According to another embodiment of the present disclosure, the inter-layer dielectric layer 22 may include one or more spaces.

A bit line structure BL and storage node contacts 23 may be disposed in the inter-layer dielectric layer 22. The bit line structure BL may be formed to be coupled to the first source/drain region 17 between the gate structures BG.

The storage node contact 23 may penetrate the inter-layer dielectric layer 22 to be coupled to the second source/drain region 17 on both sides of the gate structure BG. More specifically, a first storage node contact 23 may penetrate the inter-layer dielectric layer 22 to be coupled to one of the second source/drain regions 18 on a first side of the gate structure BG, and a second storage node contact 23 may penetrate the inter-layer dielectric layer 22 to be coupled to one of the second source/drain regions 18 on a second side of the gate structure BG.

The etch stop layer 30 may cover the inter-layer dielectric layer 22 and the storage node contact 23. The etch stop layer 30 may include a material having an etch selectivity with respect to the inter-layer dielectric layer 22 and the storage node contact 23. The etch stop layer 30 may include a dielectric material. For example, the etch stop layer 30 may include silicon nitride. The etch stop layer 30 may be used as an etching termination point when the mold structure MS is etched. The etch stop layer 30 may be formed, for example, by a Chemical Vapor Deposition (CVD) process, a Physical Vapor Deposition (PVD) process, or an Atomic Layer Deposition (ALD) process. The etch stop layer 30 may also use plasma to increase the deposition effect. The etch stop layer 30 may be formed by a method such as Plasma Enhanced Chemical Vapor Deposition (PECVD), Plasma Enhanced Atomic Layer Deposition (PEALD) and the like.

The mold structure MS may serve to provide a storage node hole for forming a lower electrode. The mold structure MS may include a stacked structure in which a plurality of supporter layers and a plurality of sacrificial layers are disposed in an alternating manner. The mold structure MS may include a stacked structure of a first sacrificial layer 40A, a first supporter layer 50A, a second sacrificial layer 41A, a second supporter layer 51A, and a third sacrificial layer 42A. According to another embodiment of the present disclosure, in the mold structure MS, the number of the sacrificial layers and the number of the supporter layers may be increased or decreased as needed.

The first to third sacrificial layers 40A, 41A and 42A may include a dielectric material. For example, each of the first to third sacrificial layers 40A, 41A and 42A may include BSG (Borosilicate Glass), PSG (Phosphosilicate Glass), BPSG (BoroPhosphosilicate Glass), or TEOS (Tetra ethyl ortho silicate). Each of the first to third sacrificial layers 40A, 41A and 42A may be a single layer. According to another embodiment of the present disclosure, each of the first to third sacrificial layers 40A, 41A and 42A may have a multi-layer structure of at least two layers. For example, BPSG and TEOS may be stacked to form a two-layer structure. According to another embodiment of the present disclosure, each of the first to third sacrificial layers 40A, 41A and 42A may include an undoped silicon layer or an amorphous silicon layer.

The first and second supporter layers 50A and 51A may include a material having an etching selectivity with respect to the first to third sacrificial layers 40A, 41A and 42A. Each of the first and second supporter layers 50A and 51A may have a thickness which is thinner than the thickness of each of the first to third sacrificial layers 40A, 41A and 42A. The difficulty of the etching process may be reduced according to the thicknesses of the first and second supporter layers 50A and 51A and the thickness of the upper supporter layer which is to be formed through a subsequent process. For example, the difficulty of the etching process may be reduced as the thicknesses of the first and second supporter layers 50A and 51A become thinner. The first and second supporter layers 50A and 51A may include a nitrogen-containing material. For example, the first and second supporter layers 50A and 51A may include silicon nitride.

Referring to FIG. 2B, openings 60 penetrating the mold structure MS and the etch stop layer 30 may be formed spaced apart from each other in a direction parallel to the plane of the top surface of the substrate 11.

Each opening 60 may be formed over a corresponding storage node contact 23. The openings 60 may be referred to as a ‘storage node holes’. The openings 60 may be formed by etching the mold structure MS using a mask layer. The mask layer may include, for example, a photoresist pattern or a hard mask pattern. In order to form the opening 60, the third sacrificial layer 42A, the second supporter layer 51A, the second sacrificial layer 41A, the first supporter layer 50A, and the first sacrificial layer 40A may be sequentially etched by using the mask layer as an etching barrier. The etching process for forming the openings 60 may stop at the etch stop layer 30. Subsequently, the etch stop layer 30 may be etched to expose the upper surface of the storage node contact 23 below the openings 60. The openings 60 may have a high aspect ratio. The aspect ratio may refer to the ratio of height to width. Each of the openings 60 may have a slope profile in which the line width becomes narrower as it goes from top to bottom.

The mold structure MS etched by the etching process may be referred to as the first to third sacrificial patterns 40, 41 and 42, and the first and second supporters 50 and 51. The etch stop layer 30 that is etched by the etching process may be referred to as an ‘etch stop pattern 30’.

Referring to FIG. 2C, a lower electrode layer 61A may be formed in the openings 60. The lower electrode layer 61A may be formed over the storage node contacts 23. The lower electrode layer 61A may be electrically connected to the storage node contacts 23.

The material for the lower electrode layer 61A may be suitable for gap-filling large aspect ratio openings 60 without leaving voids or air pockets. The lower electrode layer 61A may include a metal, a metal nitride, or a combination thereof. For example, the lower electrode layer 61A may include at least one of titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), and combinations thereof. According to an embodiment of the present disclosure, the lower electrode layer 61A may include titanium nitride (TiN). The lower electrode layer 61A may include titanium nitride (ALD-TiN) that is formed by an Atomic Layer Deposition (ALD) process, but the technical concepts and scope of the present disclosure are not limited thereto. According to another embodiment of the present disclosure, the lower electrode layer 61A may include a stacked structure of TiN/TiSiN.

Referring to FIG. 2D, a lower electrode 61 may be formed.

The lower electrode layer 61A (see FIG. 2C) may be etched targeting to expose the surface of the mold structure MS to form the lower electrode 61. As a result, the lower electrode 61 that gap-fills each one of the openings 60 may be formed. An isolation process for forming the lower electrodes 61 may include a polishing process, such as, for example, a Chemical Mechanical Polishing (CMP) process or an etch-back process.

Referring to FIG. 2E, the third sacrificial pattern 42 may be etched to a predetermined height h to expose the upper portion 61P of the lower electrode 61. The upper surface of the lower electrode 61 may be disposed at a higher level than the upper surface of the mold structure MS.

Referring to FIG. 2F, a supporter liner 52 may be formed.

The supporter liner 52 may refer to a region where the exposed surface of the upper portion 61P of the lower electrode is changed. The supporter liner 52 may cover the upper surface and a portion of a side of the lower electrode.

To form the supporter liner 52, a treatment process TM may be performed onto the upper portion 61P of the lower electrode that is exposed over the mold structure MS. For example, the treatment process TM may include an oxidation process or a nitridation process.

The supporter liner 52 may include a material having a higher work function than that of the lower electrode 61. The supporter liner 52 may include an oxide, a nitride, or an oxynitride containing the same metal material as the metal material of the lower electrode 61.

Referring to FIG. 2G, a first upper supporter layer 53 and a second upper supporter layer 54 may be sequentially formed over the supporter liner 52 and the third sacrificial pattern 42.

The first and second upper supporter layers 53 and 54 may include the same material. For example, the first and second upper supporter layers 53 and 54 may include a dielectric material selected from the group including SiOC, SiBN, SiBCN, SiCN, SiON, SiN, Si, and doped SiN.

According to another embodiment of the present disclosure, the first upper support layer 53 may include a high band gap material. According to an embodiment of the present disclosure, the high band gap material may include a material having a higher band gap than silicon nitride (SiN). For example, the high band gap material may include one oxide selected from the group including AlO, SiO, BeO, MgO, CaO, and SrO, or one nitride selected from the group including doped SiN, AlN, MoN, WN, and TaN.

Referring to FIG. 2H, a mask pattern 70 may be formed over the second upper support layer 54. The mask pattern 70 may include, for example, a photoresist pattern or a hard mask pattern.

Referring to FIG. 2I, the first and second upper support layers 53, 54 may be etched by using the mask pattern 70 (see FIG. 2H) as an etching barrier to form a first supporter hole H1.

The third sacrificial pattern 42 may be exposed through the first supporter hole H1.

Referring to FIG. 2J, the third sacrificial pattern 42 (see FIG. 2I) may be removed.

The third sacrificial pattern 42 may be removed by a wet dip-out process. The wet chemical for performing the wet dip-out process may be supplied through the first supporter hole H1. For example, one or more chemicals such as HF, NH₄F/NH₄OH, H₂O₂, HCl, HNO₃, H₂SO₄ and the like may be used as the wet chemical.

Referring to FIG. 2K, a second supporter hole H2 may be formed.

The second supporter hole H2 may be formed by using the same mask as that of the first supporter hole H1. The second supporter hole H2 may be provided by etching the second supporter 51.

Referring to FIG. 2L, the second sacrificial pattern 41 (see FIG. 2K) may be removed.

The second sacrificial pattern 41 may be removed by a wet dip-out process. The wet chemical for performing the wet dip-out process may be supplied through the second supporter hole H2. For example, one or more chemicals such as HF, NH₄F/NH₄OH, H₂O₂, HCl, HNO₃, H₂SO₄ and the like may be used as the wet chemical.

Referring to FIG. 2M, a third supporter hole H3 may be formed.

The third supporter hole H3 may be formed by using the same mask as that of the first supporter hole H1. The third supporter hole H3 may be provided by etching the first supporter 50.

Referring to FIG. 2N, the first sacrificial pattern 40 (see FIG. 2M) may be removed.

The first sacrificial pattern 40 may be removed by a wet dip-out process. The wet chemical for performing the wet dip-out process may be supplied through the third supporter hole H3. For example, one or more chemicals such as HF, NH₄F/NH₄OH, H₂O₂, HCl, HNO₃, H₂SO₄ and the like may be used as the wet chemical.

As the first to third sacrificial patterns 40, 41 and 42 are removed by the wet dip-out process illustrated in FIG. 2J to 2N, the outer wall of the lower electrode 61 may be exposed. The lower electrode 61 may be supported by the first and second supporters 50 and 51 and the upper supporter US. Therefore, the lower electrode 61 may be prevented from collapsing.

Referring to FIG. 2O, a dielectric layer 62 may be formed over the lower electrode 61, the first supporter 50, the second supporter 51, and the upper supporter US (52, 53, 54). A portion of the dielectric layer 62 may cover the etch stop pattern 30. The dielectric layer 62 may cover the first supporter 50, the second supporter 51, and the upper supporter US. The dielectric layer 62 may include a high-k material having a higher dielectric constant than silicon oxide. The high-k material may include zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃). According to another embodiment of the present disclosure, the dielectric layer 62 may be formed of a composite layer including two or more layers of the high-k materials mentioned above. According to an embodiment of the present disclosure, the dielectric layer 62 may be formed, for example, of a zirconium oxide-based material which has excellent leakage current characteristics and lowers sufficiently the equivalent oxide thickness (EOT). For example, the dielectric layer 62 may include one of ZAZ (ZrO₂/Al₂O₃/ZrO₂), TZAZ (TiO₂/ZrO₂/Al₂O₃/ZrO₂), TZAZT (TiO₂/ZrO₂/Al₂O₃/ZrO₂/TiO₂), ZAZT (ZrO₂/Al₂O₃/ZrO₂/TiO₂), TZ (TIO₂/ZrO₂), and ZAZAT (ZrO₂/Al₂O₃/ZrO₂/Al₂O₃/TiO₂). In the dielectric layer stack such as TZAZ, TZAZT, ZAZT, TZ and ZAZAT, the TiO₂ may be replaced with Ta₂O₅. The dielectric layer 62 may be formed, for example, by a Chemical Vapor Deposition (CVD) process or an Atomic Layer Deposition (ALD) process for obtaining excellent, uniform coverage.

An upper electrode 63 may be formed over the dielectric layer 62. The upper electrode 63 may include a metal-based material. For example, the upper electrode 63 may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. The upper electrode 63 may be formed by a Low-Pressure Chemical Vapor Deposition (LPCVD) process, a Plasma Enhanced Chemical Vapor Deposition (PECVD) process, or an Atomic Layer Deposition (ALD) process. According to an embodiment of the present disclosure, the upper electrode 63 may include titanium nitride (ALD-TiN) that is formed by an Atomic Layer Deposition (ALD) process.

According to another embodiment of the present disclosure, the upper electrode 63 may have a multi-layer structure. The upper electrode 63 may be formed by sequentially stacking a lower metal-containing layer, a silicon germanium layer, and an upper metal-containing layer. The lower metal-containing layer and the upper metal-containing layer may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. For example, the lower metal-containing layer may be titanium nitride, and the upper metal-containing layer may be WN/W in which tungsten nitride and tungsten are stacked. The silicon germanium layer may be doped with boron. To form the upper electrode 63, an upper electrode layer (not shown) deposition process and an upper electrode patterning process may be performed. According to another embodiment of the present disclosure, the upper electrode 63 may include a stacked structure of TiSiN/TiN or molybdenum nitride (MoN).

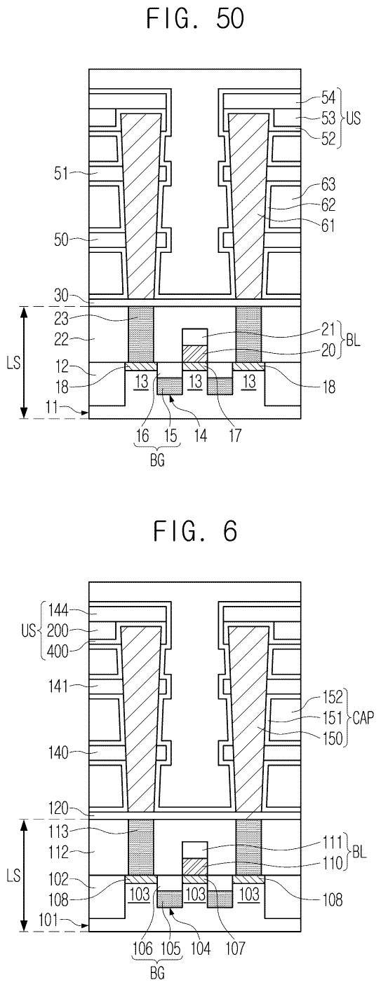

FIG. 4 is a cross-sectional view illustrating a semiconductor device in accordance with another embodiment of the present disclosure. FIG. 4 may include a structure similar to that of FIG. 1 except for a supporter liner 300. The same reference numerals may indicate the same structure. FIG. 6 is a cross-sectional view illustrating a semiconductor device in accordance with yet another embodiment of the present disclosure.

Referring to FIG. 4, the semiconductor device may include a capacitor CAP to which a supporter containing a leakage prevention material is applied to the upper portion of a substrate 101 including a lower structure LS.

The lower structure LS may include a gate structure BG disposed in the substrate 101, and a bit line BL and a storage node contact 113 that are disposed over the substrate 101.

An isolation layer 102 and an active region 103 may be formed over the substrate 101. A plurality of active regions 103 may be defined by the isolation layer 102.

The substrate 101 may be made of a material suitable for semiconductor processing.

A gate structure BG may be disposed in the substrate 101. The gate structure BG may include a buried gate structure disposed at a lower level than the upper surface of the substrate 101. Although FIG. 1 illustrates a buried gate structure disposed at a lower level than the upper surface of the substrate 101, the technical concepts and scope of the present disclosure are not limited thereto. Any suitable gate structure including a recess gate, a fin gate, a planar gate and the like may be applied.

The gate structure BG may include a stacked structure of a gate electrode 105 and a gate capping layer 106 that gap-fill the gate trench 104. A gate dielectric layer may be interposed between the gate trench 104 and the stacked structure of the gate electrode 105 and the gate capping layer 106.

First and second impurity regions 107 and 108 may be formed in the substrate 101. The first and second impurity regions 107 and 108 may be referred to as ‘first and second source/drain regions’, respectively. The first and second impurity regions 107 and 108 may be spaced apart from each other by the gate trench 104. The gate electrode 105 and the first and second impurity regions 107 and 108 may become a cell transistor. The cell transistor may improve the short channel effect due to the gate electrode 105 having a buried gate structure.

An inter-layer dielectric layer 112 may be disposed over the substrate 101. For example, the inter-layer dielectric layer 112 may include a suitable dielectric material including, for example, at least one of silicon nitride, silicon oxide, and silicon oxynitride. According to another embodiment of the present disclosure, the inter-layer dielectric layer 112 may include one or more spaces.

A bit line structure BL and a storage node contact 113 may be disposed in the inter-layer dielectric layer 112. The bit line structure BL may be formed to be coupled to the first source/drain region 107 between the gate structures BG.

The storage node contact 113 may penetrate the inter-layer dielectric layer 112 to be coupled to the second source/drain region 107 on both sides of the gate structure BG.

An etch stop pattern 120 may be disposed over the inter-layer dielectric layer 112. The etch stop pattern 120 may cover the inter-layer dielectric layer 112 and expose the storage node contact 113. The etch stop pattern 120 may include a dielectric material.

Lower electrodes 150 may be respectively disposed over the storage node contacts 113. The lower electrodes 150 may penetrate the etch stop pattern 120 and may be electrically connected to the storage node contacts 113, respectively. The lower electrode 150 may have a high aspect ratio. Here, the high aspect ratio may refer to the ratio of height to width. The lower electrode 150 may refer to an aspect ratio which is greater than approximately 1:1. The lower electrode 150 may have an aspect ratio of approximately 10:1 or more. The height of the lower electrode 150 may be approximately 5000 Å or more. For example, the lower electrodes 150 may have a pillar shape. According to another embodiment of the present disclosure, the lower electrodes 150 may include a cylinder shape.

The lower electrodes 150 may include a conductive material. For example, the lower electrodes 150 may include cobalt (Co), titanium (Ti), nickel (Ni), tungsten (W), molybdenum (Mo), gold (Pt), ruthenium (Ru), iridium (Ir), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), tungsten nitride (WN), or a combination thereof. The lower electrode 150 may be formed of titanium nitride. The lower electrode 150 may include titanium nitride (ALD-TiN) that is formed by an Atomic Layer Deposition (ALD) process. According to another embodiment of the present disclosure, the lower electrode 150 may include a stacked structure of TiN/TiSiN.

A plurality of supporters 140, 141 and US may be disposed over the substrate 101. The supporters 140, 141 and US may be spaced apart from each other in a direction perpendicular to the upper surface of the substrate 101. The supporters 140, 141 and US may include a first supporter 140, a second supporter 141, and an upper supporter US. The first and second supporters 140 and 141 may be referred to as ‘lower supporters’. The number of the lower supporters may be increased or decreased as needed.

The supporters 140, 141 and US may be disposed between the lower electrodes 150. The supporters 140, 141 and US may contact the side of each lower electrode 150 to surround the side of each lower electrode 150. The supporters 140, 141 and US may physically support the lower electrodes 150. The supporters 140, 141 and US may contact the side walls of the neighboring lower electrodes 150. The upper supporter US may be thicker than each of the first and second supporters 140 and 141.

The first and second supporters 140 and 141 may include a dielectric material. For example, the first and second supporters 140 and 141 may include silicon nitride.

The upper supporter US may be formed in multiple layers. The upper supporter US may be disposed between the neighboring lower electrodes 150 and over the lower electrodes 150. The upper supporter US may include a stacked structure of a supporter liner 300, a first upper supporter 143, and a second upper supporter 144. The supporter liner 300 may cover the upper surface and a portion of a side of each lower electrode 150. The supporter liner 300 may extend in a direction parallel to the surface of the substrate 101.

The first upper supporter 143 may gap-fill the upper portion of the supporter liner 142 and between the supporter liners 300. The second upper supporter 144 may be disposed over the first upper supporter 143.

The supporter liner 300 may include a high band gap material. The high band gap material may include a material having a higher band gap than silicon nitride (SiN). The supporter liner 300 may be formed through a deposition process. For example, the high band gap material may include one oxide selected from the group including AlO, SiO, BeO, MgO, CaO, and SrO, or one nitride selected from the group including doped SiN, AlN, MoN, WN, and TaN.

The first and second upper supporters 143 and 144 may include the same material. For example, the first and second upper supporters 143 and 144 may include a dielectric material selected from the group including SiOC, SiBN, SiBCN, SiCN, SiON, SiN, Si, and doped SiN.

According to another embodiment of the present disclosure, referring to FIG. 6, the first upper supporter 200 may include a high band gap material. According to an embodiment of the present disclosure, the high band gap material may include a material having a higher band gap than silicon nitride (SiN). For example, the high band gap material may include one oxide selected from the group including AlO, SiO, BeO, MgO, CaO, and SrO, or one nitride selected from the group including doped SiN, AlN, MoN, WN, and TaN. The supporter liner 300 and the second upper supporter 144 may include a dielectric material selected from the group including SiOC, SiBN, SiBCN, SiCN, SiON, SiN, Si, and doped SiN.

The dielectric layer 151 may uniformly cover the surfaces of the lower electrodes 150 and the supporters 140, 141 and US.

An upper electrode 152 may be formed over the dielectric layer 151. The dielectric layer 151 and the upper electrode 152 may include the same material as those of the dielectric layer 151 and the upper electrode 152 shown in FIG. 1.

As described above, the leakage current between cells may be mitigated or minimized by forming the supporter liner 300 or the first upper supporter 200 of a high band gap material.

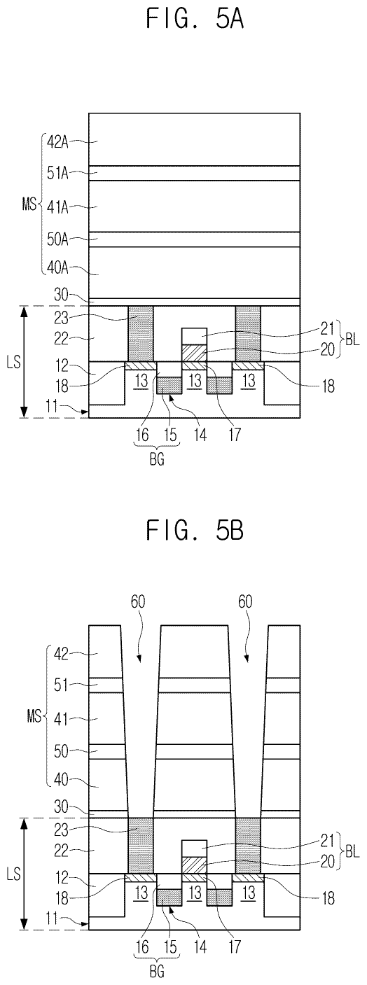

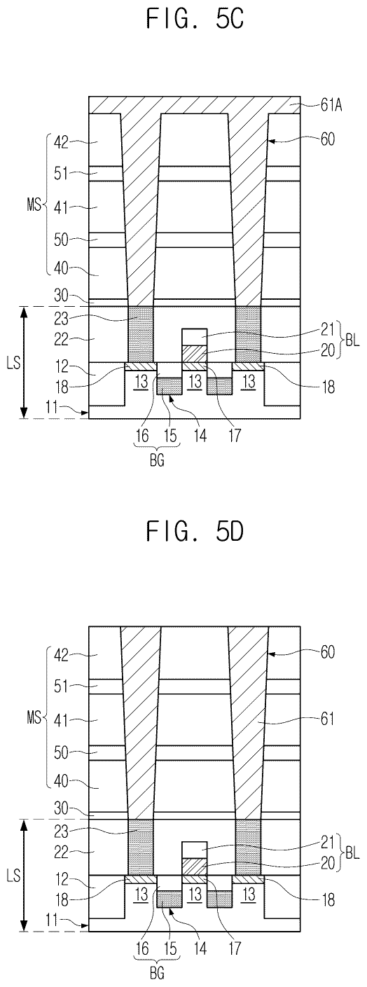

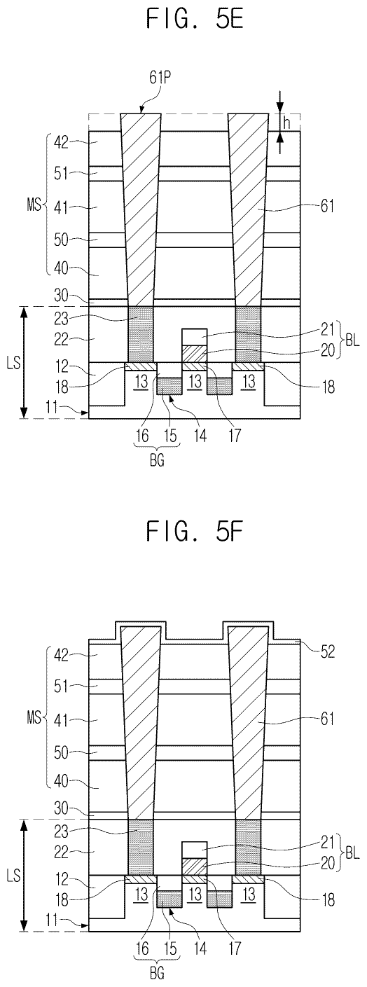

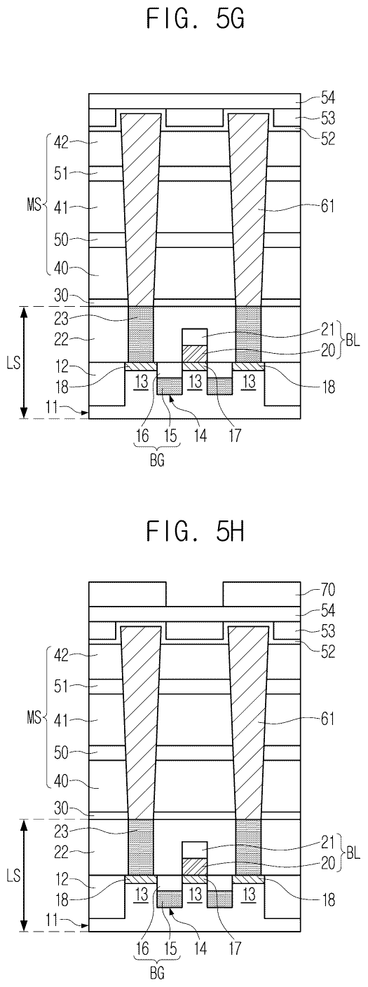

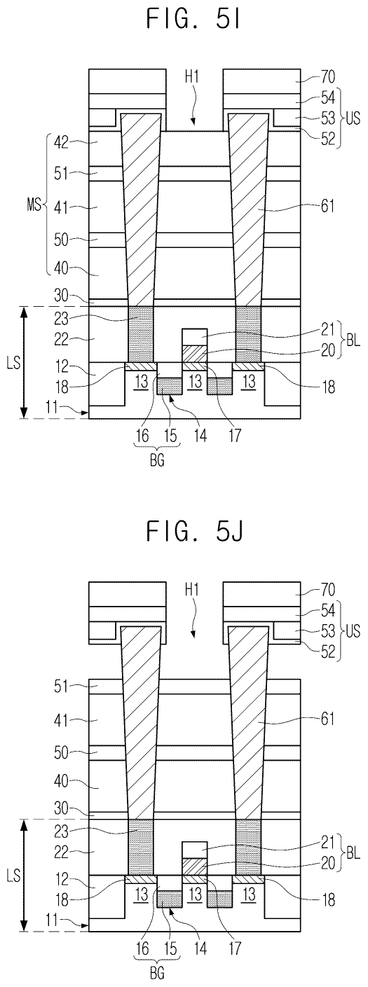

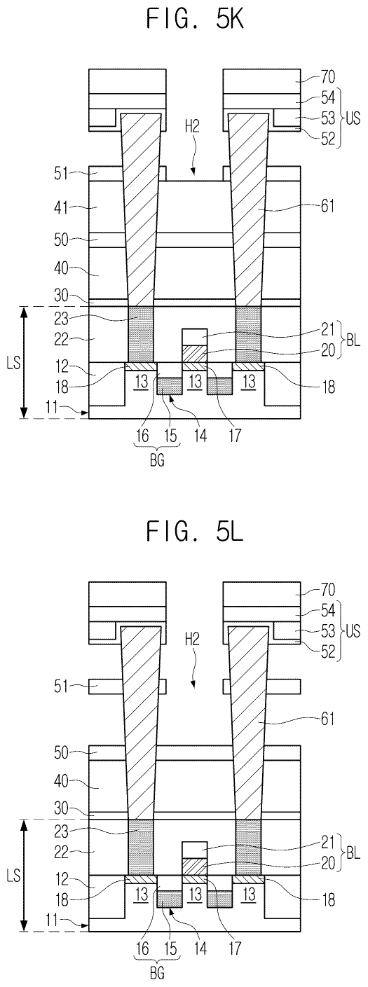

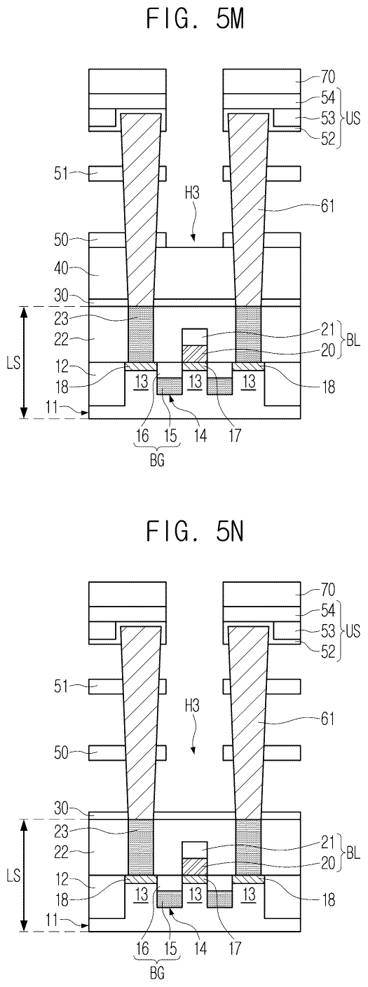

FIGS. 5A to 5O are process cross-sectional views illustrating a method for fabricating a semiconductor device in accordance with another embodiment of the present disclosure.

Referring to FIG. 5A, an etch stop layer 30 and a mold structure MS may be sequentially formed over the substrate 11 including the lower structure LS.

The lower structure LS may include a gate structure BG disposed in the substrate 11. The lower structure LS may also include a bit line BL and a storage node contact 23 that are disposed over the substrate 11.

The substrate 11 may be made of a material suitable for semiconductor processing.

An isolation layer 12 may be formed over the substrate 11 defining a plurality of active regions 13.

A gate structure BG may be disposed in the substrate 11. The gate structure BG may include a buried gate structure disposed at a lower level than the upper surface of the substrate 11. Although FIG. 5A illustrates a buried gate structure disposed at a lower level than the upper surface of the substrate 11, the technical concepts and scope of the present disclosure are not limited thereto. Any suitable gate structure including a recess gate, a fin gate, a planar gate and the like may be applied.

The gate structure BG may include a stacked structure of a gate electrode 15 and a gate capping layer 16 that gap-fill a gate trench 14. A gate dielectric layer may be interposed between the gate trench 14 and the stacked structure of the gate electrode 15 and the gate capping layer 16.

For example, the gate trench 14 may be formed in the substrate 11. The bottom surface of the gate trench 14 may be disposed at a higher level than the bottom surface of the isolation layer 12. The gate trench 14 may have a shallower depth than the isolation layer 12. According to another embodiment of the present disclosure, the bottom portion of the gate trench 14 may have a curvature. According to another embodiment of the present disclosure, the isolation layer 102 of the direction in which the gate trench 14 extends may be etched to a predetermined depth to form a fin in the active region 13.

The gate electrode 15 may fill the bottom portion of the gate trench 14. The gate capping layer 16 may fill the remaining portion of the gate trench 14 over the gate electrode 15. The upper surface of the gate capping layer 16 may be disposed at the same level as the upper surface of the substrate 11.

The first and second impurity regions 17 and 18 may be formed in the substrate 11. The first and second impurity regions 17 and 18 may be referred to as ‘first and second source/drain regions’, respectively. The first and second impurity regions 17 and 18 may be spaced apart from each other by the gate trench 14. The gate electrode 15 and the first and second impurity regions 17 and 18 may become a cell transistor. The cell transistor may improve the short channel effect due to the gate electrode 15 having a buried gate structure.

An inter-layer dielectric layer 22 may be disposed over the substrate 11. For example, the inter-layer dielectric layer 22 may include a suitable dielectric material including, for example, at least one of silicon nitride, silicon oxide, and silicon oxynitride. According to another embodiment of the present disclosure, the inter-layer dielectric layer 22 may include one or more spaces.

A bit line structure BL and storage node contacts 23 may be disposed in the inter-layer dielectric layer 22. The bit line structure BL may be formed to be coupled to the first source/drain region 17 between the gate structures BG.

The storage node contact 23 may penetrate the inter-layer dielectric layer 22 to be coupled to the second source/drain region 18 on both sides of the gate structure BG. More specifically, a first storage node contact 23 may penetrate the inter-layer dielectric layer 22 to be coupled to one of the second source/drain regions 18 on a first side of the gate structure BG, and a second storage node contact 23 may penetrate the inter-layer dielectric layer 22 to be coupled to one of the second source/drain regions 18 on a second side of the gate structure BG.

The etch stop layer 30 may cover the inter-layer dielectric layer 22 and the storage node contact 23. The etch stop layer 30 may include a material having an etch selectivity with respect to the inter-layer dielectric layer 22 and the storage node contact 23. The etch stop layer 30 may include a dielectric material. For example, the etch stop layer 30 may include silicon nitride. The etch stop layer 30 may be used as an etching termination point when the mold structure MS is etched. The etch stop layer 30 may be formed, for example, by a Chemical Vapor Deposition (CVD) process, a Physical Vapor Deposition (PVD) process, or an Atomic Layer Deposition (ALD) process. The etch stop layer 30 may also use plasma to increase the deposition effect. The etch stop layer 30 may be formed by a method such as Plasma Enhanced Chemical Vapor Deposition (PECVD), Plasma Enhanced Atomic Layer Deposition (PEALD) and the like.

The mold structure MS may serve to provide a storage node hole for forming a lower electrode. The mold structure MS may include a stacked structure in which a plurality of supporter layers and a plurality of sacrificial layers are disposed in an alternating manner. The mold structure MS may include a stacked structure of a first sacrificial layer 40A, a first supporter layer 50A, a second sacrificial layer 41A, a second supporter layer 51A, and a third sacrificial layer 42A. According to another embodiment of the present disclosure, in the mold structure MS, the number of the sacrificial layers and the number of the supporter layers may be increased or decreased as needed.

The first to third sacrificial layers 40A, 41A and 42A may include a dielectric material. For example, each of the first to third sacrificial layers 40A, 41A and 42A may include BSG (Borosilicate Glass), PSG (Phosphosilicate Glass), BPSG (BoroPhosphosilicate Glass), or TEOS (Tetra ethyl ortho silicate). Each of the first to third sacrificial layers 40A, 41A and 42A may be a single layer. According to another embodiment of the present disclosure, each of the first to third sacrificial layers 40A, 41A and 42A may have a multi-layer structure of at least two layers. For example, BPSG and TEOS may be stacked. According to another embodiment of the present disclosure, each of the first to third sacrificial layers 40A, 41A and 42A may include an undoped silicon layer or an amorphous silicon layer.

The first and second supporter layers 50A and 51A may include a material having an etching selectivity with respect to the first to third sacrificial layers 40A, 41A and 42A. Each of the first and second supporter layers 50A and 51A may have a thickness which is thinner than the thickness of each of the first to third sacrificial layers 40A, 41A and 42A. The difficulty of the etching process may be reduced according to the thicknesses of the first and second supporter layers 50A and 51A and the thickness of the upper supporter layer which is to be formed through a subsequent process. For example, the difficulty of the etching process may be reduced as the thicknesses of the first and second supporter layers 50A and 51A become thinner. The first and second supporter layers 50A and 51A may include a nitrogen-containing material. For example, the first and second supporter layers 50A and 51A may include silicon nitride.

Referring to FIG. 5B, openings 60 penetrating the mold structure MS may be formed spaced apart from each other. in a direction parallel to the plane of the top surface of the substrate 11. Each of the openings 60 may be formed over a corresponding storage node contact 23. The openings 60 may be referred to as a ‘storage node holes’. The openings 60 may be formed by etching the mold structure MS using a mask layer. The mask layer may include, for example, a photoresist pattern or a hard mask pattern. In order to form the opening 60, the third sacrificial layer 42A, the second supporter layer 51A, the second sacrificial layer 41A, the first supporter layer 50A, and the first sacrificial layer 40A may be sequentially etched by using the mask layer as an etching barrier. The etching process for forming the opening 60 may stop at the etch stop layer 30. Subsequently, the etch stop layer 30 may be etched to expose the upper surface of the storage node contact 23 below the opening 60. The opening 60 may have a high aspect ratio. The aspect ratio may refer to the ratio of height to width.

The mold structures MS etched by the etching process may be referred to as the first to third sacrificial patterns 40, 41 and 42 and the first and second supporters 50 and 51. The etch stop layer 30 etched by the etching process may be referred to as an ‘etch stop pattern 30’.

Referring to FIG. 5C, a lower electrode layer 61A may be formed in the opening 60. The lower electrode layer 61A may be formed over the storage node contact 23. The lower electrode layer 61A may be electrically connected to the storage node contact 23.

The lower electrode layer 61A may include a metal, a metal nitride, or a combination thereof. For example, the lower electrode layer 61A may include at least one of titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), and combinations thereof. According to an embodiment of the present disclosure, the lower electrode layer 61A may include titanium nitride (TiN). The lower electrode layer 61A may include titanium nitride (ALD-TiN) that is formed by an atomic layer deposition (ALD) process, but the technical concepts and scope of the present disclosure are not limited thereto. According to another embodiment of the present disclosure, the lower electrode layer 61A may include a stacked structure of TiN/TiSiN.

Referring to FIG. 5D, a lower electrode 61 may be formed.

To form the lower electrode 61, the lower electrode layer 61A (see FIG. 5C) may be etched targeting to expose the surface of the mold structure MS. As a result, the lower electrode 61 that gap-fills the opening 60 may be formed. An isolation process for forming the lower electrode 61 may include a polishing process. For example, the polishing process may include a Chemical Mechanical Polishing (CMP) process or an etch-back process.

Referring to FIG. 5E, the third sacrificial pattern 42 may be etched to a predetermined height h to expose the upper portion 61P of the lower electrode. The upper surface of the lower electrode 61 may be disposed at a higher level than the upper surface of the mold structure MS.

Referring to FIG. 5F, a supporter liner 52 may be formed.

The support liner 52 may be uniformly deposited along the exposed upper portion 61P of the lower electrode and the third sacrificial pattern 42. The support liner 52 may have a liner shape that covers the surface of the third sacrificial pattern 42, the upper surface of the lower electrode 61, and a portion of the side of the lower electrode 61.

The support liner 52 may include a high band gap material. The high band gap material may include a material having a higher band gap than silicon nitride (SiN). For example, the high band gap material may include one oxide selected from the group including AlO, SiO, BeO, MgO, CaO, and SrO, or one nitride selected from the group including doped SiN, AlN, MoN, WN, and TaN.

Referring to FIG. 5G, a first upper supporter layer 53 and a second upper supporter layer 54 may be sequentially formed over the supporter liner 52 and the third sacrificial pattern 42.

The first and second upper supporter layers 53 and 54 may include the same material. For example, the first and second upper supporter layers 53 and 54 may include a dielectric material selected from the group including SiOC, SiBN, SiBCN, SiCN, SiON, SiN, Si, and doped SiN.

According to another embodiment of the present disclosure, the first upper supporter layer 53 may include a high band gap material. The high band gap material may include a material having a higher band gap than silicon nitride (SiN). For example, the high band gap material may include one oxide selected from the group including AlO, SiO, BeO, MgO, CaO, and SrO, or one nitride selected from the group including doped SiN, AlN, MoN, WN, and TaN. Here, the support liner 52 formed in FIG. 5F may include a dielectric material selected from the group including SiOC, SiBN, SiBCN, SiCN, SiON, SiN, Si, and doped SiN.

Referring to FIG. 5H, a mask pattern 70 may be formed over the second upper support layer 54. The mask pattern 70 may include, for example, a photoresist pattern or a hard mask pattern.

Referring to FIG. 5I, the upper supporter US may be etched by using the mask pattern 70 (see FIG. 5H) as an etching barrier to form a first supporter hole H1.

The third sacrificial pattern 42 may be exposed through the first supporter hole H1.

Referring to FIG. 5J, the third sacrificial pattern 42 (see FIG. 5I) may be removed.

The third sacrificial pattern 42 may be removed by a wet dip-out process. The wet chemical for performing the wet dip-out process may be supplied through the first supporter hole H1. For example, one or more chemicals such as HF, NH₄F/NH₄OH, H₂O₂, HCl, HNO₃, H₂SO₄ and the like may be used as the wet chemical.

Referring to FIG. 5K, a second supporter hole H2 may be formed.

The second supporter hole H2 may be formed by using the same mask as that of the first supporter hole H1. The second supporter hole H2 may be provided by etching the second supporter 51.

Referring to FIG. 5L, the second sacrificial pattern 41 (see FIG. 5K) may be removed.

The second sacrificial pattern 41 may be removed by a wet dip-out process. The wet chemical for performing the wet dip-out process may be supplied through the second supporter hole H2. For example, one or more chemicals such as HF, NH₄F/NH₄OH, H₂O₂, HCl, HNO₃, H₂SO₄ and the like may be used as the wet chemical.

Referring to FIG. 5M, a third supporter hole H3 may be formed.

The third supporter hole H3 may be formed by using the same mask as that of the first supporter hole H1. The third supporter hole H3 may be provided by etching the first supporter 50.

Referring to FIG. 5N, the first sacrificial pattern 40 (see FIG. 5M) may be removed.

The first sacrificial pattern 40 may be removed by a wet dip-out process. The wet chemical for performing the wet dip-out process may be supplied through the third supporter hole H3. For example, one or more chemicals such as HF, NH₄F/NH₄OH, H₂O₂, HCl, HNO₃, H₂SO₄ and the like may be used as the wet chemical.

As the first to third sacrificial patterns 40, 41 and 42 are removed by the wet dip-out process illustrated in FIG. 5J to 5N, the outer wall of the lower electrode 61 may be exposed. The lower electrode 61 may be supported by the first and second supporters 50 and 51 and the upper supporter US. Therefore, the lower electrode 61 may be prevented from collapsing.

Referring to FIG. 5O, a dielectric layer 62 may be formed over the lower electrode 61, the first supporter 50, the second supporter 51, and the upper supporter US. A portion of the dielectric layer 62 may cover the etch stop pattern 30. The dielectric layer 62 may cover the first supporter 50, the second supporter 51, and the upper supporter US. The dielectric layer 62 may include a high-k material having a higher dielectric constant than silicon oxide. The high-k material may include zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃). According to another embodiment of the present disclosure, the dielectric layer 62 may be formed of a composite layer including two or more layers of the high-k materials mentioned above. According to an embodiment of the present disclosure, the dielectric layer 62 may be formed, for example, of a zirconium oxide-based material which has excellent leakage current characteristics and lowers sufficiently the equivalent oxide thickness (EOT). For example, the dielectric layer 62 may include one of ZAZ (ZrO₂/Al₂O₃/ZrO₂), TZAZ (TiO₂/ZrO₂/Al₂O₃/ZrO₂), TZAZT (TiO₂/ZrO₂/Al₂O₃/ZrO₂/TiO₂), ZAZT (ZrO₂/Al₂O₃/ZrO₂/TiO₂), TZ (TIO₂/ZrO₂), and ZAZAT (ZrO₂/Al₂O₃/ZrO₂/Al₂O₃/TiO₂). In the dielectric layer stack such as TZAZ, TZAZT, ZAZT, TZ and ZAZAT, the TiO₂ may be replaced with Ta₂O₅. The dielectric layer 62 may be formed, for example, by a Chemical Vapor Deposition (CVD) process or an Atomic Layer Deposition (ALD) process for obtaining excellent, uniform coverage.

An upper electrode 63 may be formed over the dielectric layer 62. The upper electrode 63 may include a metal-based material. For example, the upper electrode 63 may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. The upper electrode 63 may be formed by a Low-Pressure Chemical Vapor Deposition (LPCVD) process, a Plasma Enhanced Chemical Vapor Deposition (PECVD) process, or an Atomic Layer Deposition (ALD) process. According to an embodiment of the present disclosure, the upper electrode 63 may include titanium nitride (ALD-TiN) that is formed by an atomic layer deposition (ALD) process.

According to another embodiment of the present disclosure, the upper electrode 63 may have a multi-layer structure. The upper electrode 63 may be formed by sequentially stacking a lower metal-containing layer, a silicon germanium layer, and an upper metal-containing layer. The lower metal-containing layer and the upper metal-containing layer may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. For example, the lower metal-containing layer may be titanium nitride, and the upper metal-containing layer may be WN/W in which tungsten nitride and tungsten are stacked. The silicon germanium layer may be doped with boron. To form the upper electrode 63, an upper electrode layer (not shown) deposition process and an upper electrode patterning process may be performed. According to another embodiment of the present disclosure, the upper electrode 63 may include a stacked structure of TiSiN/TiN or molybdenum nitride (MoN).

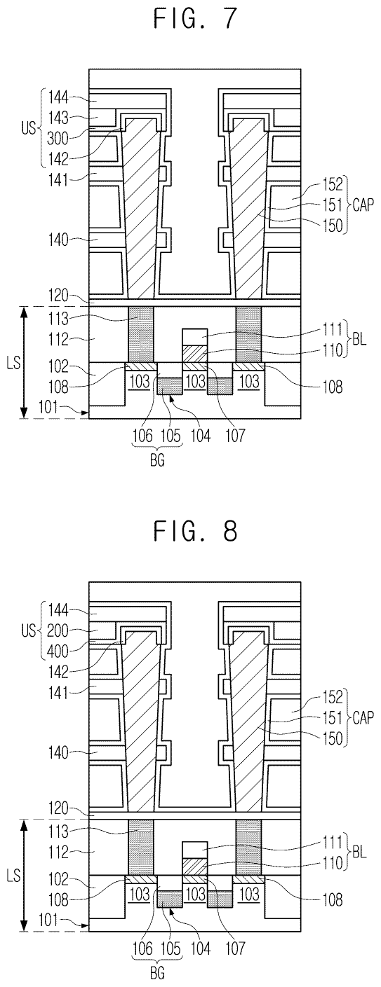

FIGS. 7 and 8 are cross-sectional views illustrating semiconductor devices in accordance with other embodiments of the present disclosure. FIGS. 7 and 8 may show a structure similar to what is illustrated in FIG. 1 except for the structure of the upper supporter US.

Referring to FIG. 7, the semiconductor device may include a substrate 101, a lower electrode 150 formed over the substrate 101, and a supporter covering an upper surface and a portion of a side of the lower electrode 150 and including a material having a higher work function than that of the lower electrode 150.

The lower electrodes 150 may be respectively disposed over the storage node contact 113. The lower electrodes 150 may penetrate the etch stop pattern 120 and may be electrically connected to the storage node contacts 113, respectively. The lower electrodes 150 may have a high aspect ratio. Here, the aspect ratio may refer to the ratio of height to width. The lower electrode 150 may refer to an aspect ratio which is greater than approximately 1:1. The lower electrode 150 may have an aspect ratio of approximately 10:1 or more. The height of the lower electrode 150 may be approximately 5000 Å or more. For example, the lower electrodes 150 may have a pillar shape. According to another embodiment of the present disclosure, the lower electrodes 150 may include a cylinder shape.

The lower electrodes 150 may include a conductive material. For example, the lower electrodes 150 may include cobalt (Co), titanium (Ti), nickel (Ni), tungsten (W), molybdenum (Mo), gold (Pt), ruthenium (Ru), iridium (Ir), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), tungsten nitride (WN), or a combination thereof. The lower electrode 150 may be formed of titanium nitride. The lower electrode 150 may include titanium nitride (ALD-TiN) that is formed by an atomic layer deposition (ALD) process. According to another embodiment of the present disclosure, the lower electrode 150 may include a stacked structure of TiN/TiSiN.

A plurality of supporters 140, 141 and US may be disposed over the substrate 101. The supporters 140, 141 and US may be spaced apart from each other in a direction perpendicular to the surface of the substrate 101. The supporters 140, 141 and US may include a first supporter 140, a second supporter 141, and an upper supporter US. The first and second supporters 140 and 141 may be referred to as ‘lower supporters’. The number of the lower supporters may be increased or decreased as needed.

The supporters 140, 141 and US may be disposed between the lower electrodes 150. The supporters 140, 141 and US may contact the side of each lower electrode 150 to surround the side of each lower electrode 150. The supporters 140, 141 and US may physically support the lower electrodes 150. The supporters 140, 141 and US may contact the side walls of the neighboring lower electrodes 150. The upper supporter US may be thicker than each of the first and second supporters 140 and 141.

The first and second supporters 140 and 141 may include a dielectric material. For example, the first and second supporters 140 and 141 may include silicon nitride.

The upper supporter US may be formed in multiple layers. The upper supporter US may be disposed between the neighboring lower electrodes 150 and over the lower electrodes 150. The upper supporter US may include a stacked structure of a first supporter liner 142, a second supporter liner 300, a first upper supporter 143, and a second upper supporter 144.

The first supporter liner 142 may cover the upper surface and a portion of a side of each lower electrode 150. The second supporter liner 300 may extend in a direction parallel to the surface of the substrate 101 while covering the outer wall of the first supporter liner 142. The first upper supporter 143 may gap-fill the upper portion of the second supporter liner 300 and between the second supporter liners 300. The second upper supporter 144 may be disposed over the first upper supporter 143.

The upper supporter US may include a material having a higher work function than that of the lower electrode 150 and a high band gap material. According to an embodiment of the present disclosure, the high band gap material may include a material having a higher band gap than silicon nitride (SiN). According to an embodiment of the present disclosure, the first supporter liner 142 may include a material having a higher work function than that of the lower electrode 150. The first supporter liner 142 may be formed through a treatment process. The first supporter liner 142 may be a region where the surface of the lower electrode 150 is changed with a material having a higher work function than that of the lower electrode 150 by performing a treatment process onto the surface of the lower electrode 150.

For example, the treatment process may include an oxidation process or a nitridation process.

The first supporter liner 142 may be an oxide, a nitride, or an oxynitride including the same metal material as the metal material of the lower electrode 150.

The second supporter liner 300 may include a high band gap material. The high band gap material may include a material having a higher band gap than silicon nitride (SiN). The high band gap material may be formed through a deposition process. For example, the high band gap material may include one oxide selected from the group including AlO, SiO, BeO, MgO, CaO, and SrO, or one nitride selected from the group including doped SiN, AlN, MoN, WN, and TaN.

The first and second upper supporters 143 and 144 may include the same material. For example, the first and second upper supporters may include a dielectric material selected from the group including SiOC, SiBN, SiBCN, SiCN, SiON, SiN, Si, and doped SiN.

According to another embodiment of the present disclosure, referring to FIG. 8, the first upper supporter 200 may include a high band gap material. The high band gap material may include a material having a higher band gap than silicon nitride (SiN). The high band gap material may be formed through a deposition process. For example, the high band gap material may include one oxide selected from the group including AlO, SiO, BeO, MgO, CaO, and SrO, or one nitride selected from the group including doped SiN, AlN, MoN, WN, and TaN.

The dielectric layer 151 may uniformly cover the surfaces of the lower electrodes 150 and the supporters 140, 141 and US. The dielectric layer 151 may not be disposed between the first supporter 140 and the lower electrode 150. Also, the dielectric layer 151 may not be disposed between the second supporter 141 and the lower electrode 150.

The dielectric layer 151 may include a high-k material having a higher dielectric constant than silicon oxide. The high-k material may include zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃). According to another embodiment of the present disclosure, the dielectric layer 151 may be formed of a composite layer including two or more layers of the aforementioned high-k materials. The dielectric layer 151 may be formed, for example, of a zirconium oxide-based material which has excellent leakage current characteristics and lowers sufficiently the equivalent oxide thickness (EOT). For example, the dielectric layer 151 may include one of ZAZ (ZrO₂/Al₂O₃/ZrO₂), TZAZ (TiO₂/ZrO₂/Al₂O₃/ZrO₂), TZAZT (TiO₂/ZrO₂/Al₂O₃/ZrO₂/TiO₂), ZAZT (ZrO₂/Al₂O₃/ZrO₂/TiO₂), TZ (TIO₂/ZrO₂), and ZAZAT (ZrO₂/Al₂O₃/ZrO₂/Al₂O₃/TiO₂). In the dielectric layer stack such as TZAZ, TZAZT, ZAZT, TZ, and ZAZAT, the TiO₂ may be replaced with Ta₂O₅. The dielectric layer 151 may be formed, for example, by a Chemical Vapor Deposition (CVD) process or an Atomic Layer Deposition (ALD) process for obtaining excellent, uniform coverage.

An upper electrode 152 may be formed over the dielectric layer 151. The upper electrode 152 may include a metal-based material. For example, the upper electrode 152 may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. The upper electrode 152 may be formed by a Low-Pressure Chemical Vapor Deposition (LPCVD) process, a Plasma Enhanced Chemical Vapor Deposition (PECVD) process, or an Atomic Layer Deposition (ALD) process. According to an embodiment of the present disclosure, the upper electrode 152 may include titanium nitride (ALD-TiN) that is formed by an atomic layer deposition (ALD) process.

According to another embodiment of the present disclosure, the upper electrode 152 may have a multi-layer structure. The upper electrode 152 may be formed by sequentially stacking a lower metal-containing layer, a silicon germanium layer, and an upper metal-containing layer. The lower metal-containing layer and the upper metal-containing layer may include titanium (Ti), titanium nitride (TN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. For example, the lower metal-containing layer may be titanium nitride, and the upper metal-containing layer may be WN/W in which tungsten nitride and tungsten are stacked. The silicon germanium layer may be doped with boron. According to another embodiment of the present disclosure, the upper electrode 152 may include a stacked structure of TiSiN/TiN or molybdenum nitride (MoN).

According to the embodiments of the present disclosure, it is possible to prevent leakage current between cells.

The reliability of semiconductor devices may be improved.

While the embodiments of the present disclosure have been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device comprising:
a lower electrode formed over a substrate; and
a supporter covering an upper surface and a portion of a side of the lower electrode and including a material having a higher work function than a material of the lower electrode.

2. The semiconductor device of claim 1, wherein the supporter includes an oxide, a nitride, or an oxynitride of a metal material that is identical to a metal material of the lower electrode.

3. The semiconductor device of claim 1, wherein the supporter further includes:
a supporter liner covering an upper surface and a portion of a side of the lower electrode and including a material having a higher work function than a material of the lower electrode;
a first upper supporter gap-filling an upper portion of the supporter liner and a space between neighboring lower electrodes; and
a second upper supporter disposed over the first upper supporter.

4. The semiconductor device of claim 3, wherein the first and second upper supporters include a dielectric material selected from a group including SiOC, SiBN, SiBCN, SiCN, SiON, SiN, Si, and doped SiN.

5. The semiconductor device of claim 3, wherein the first upper supporter includes a high band gap material having a higher band gap than silicon nitride, and
the second upper supporter includes a dielectric material selected from a group including SiOC, SiBN, SiBCN, SiCN, SiON, SiN, Si, and doped SiN.

6. The semiconductor device of claim 5, wherein the high band gap material includes,
one oxide selected from a group including AlO, SiO, BeO, MgO, CaO, and SrO, or
one nitride selected from a group including doped SiN, AlN, MoN, WN, and TaN.

7. The semiconductor device of claim 3, wherein the supporter liner has a thinner thickness than each of the first and second upper supporters.

8. The semiconductor device of claim 1, further comprising:
a dielectric layer covering the lower electrode and the supporter; and
an upper electrode over the dielectric layer.

9. A semiconductor device comprising:
a lower electrode formed over a substrate;
a lower supporter suitable for surrounding a portion of an outer wall of the lower electrode; and
an upper supporter covering an upper surface and a portion of a side of the lower electrode and including a high band gap material having a higher band gap than a material of the lower supporter.

10. The semiconductor device of claim 9, wherein the upper supporter includes:
a supporter liner covering the upper surface and the portion of the side of the lower electrode, the supporter liner including a high band gap material having a higher band gap than the material of the lower supporter;
a first upper supporter gap-filling an upper portion of the supporter liner and between neighboring lower electrodes; and
a second upper supporter over the first upper supporter.

11. The semiconductor device of claim 9, wherein the lower supporter includes silicon nitride.

12. The semiconductor device of claim 10, wherein the first and second upper supporters include a dielectric material selected from a group including SiOC, SiBN, SiBCN, SiCN, SiON, SiN, Si, and doped SiN.

13. The semiconductor device of claim 9, wherein the high band gap material includes,
one oxide selected from a group including AlO, SiO, BeO, MgO, CaO, and SrO, or
one nitride selected from a group including doped SiN, AlN, MoN, WN, and TaN.

14. The semiconductor device of claim 9, wherein the upper supporter includes:
a supporter liner covering the upper surface and the portion of the side of the lower electrode;
a first upper supporter gap-filling an upper portion of the supporter liner and between neighboring lower electrodes, the first upper supporter including a high band gap material having a higher band gap than the material of the lower supporter; and
a second upper supporter over the first upper supporter.

15. The semiconductor device of claim 14, wherein the supporter liner and the second upper supporter include
a dielectric material selected from a group including SiOC, SiBN, SiBCN, SiCN, SiON, SiN, Si, and doped SiN.

16. The semiconductor device of claim 14, wherein the high band gap material includes,
one oxide selected from a group including AlO, SiO, BeO, MgO, CaO, and SrO, or
one nitride selected from a group including doped SiN, AlN, MoN, WN, and TaN.

17. The semiconductor device of claim 9, wherein the supporter liner extends from a side of the lower electrode into between the neighboring lower electrodes.

18. The semiconductor device of claim 10, wherein the supporter liner has a thinner thickness than each of the first and second upper supporters.

19. The semiconductor device of claim 9, further comprising:
a dielectric layer covering the lower electrode, the lower supporter, and the upper supporter; and
an upper electrode over the dielectric layer.

20. A semiconductor device comprising:
a lower electrode formed over a substrate; and
a supporter including a supporter liner covering an upper surface and a portion of a side of the lower electrode and including a material having a higher work function than a material of the lower electrode.
